(19) United States
(12) Patent Application Publication
(10) Pub. No.: US 2025/0121736 A1
(43) Pub. Date: Apr. 17, 2025

(54) ELECTRIC VEHICLE

(71) Applicant: TOYOTA JIDOSHA KABUSHIKI KAISHA, Toyota-shi (JP)

(72) Inventors: Kouichi YOKOYAMA, Toyota-shi (JP); Hironori HARADA, Nukata-gun (JP)

(73) Assignee: TOYOTA JIDOSHA KABUSHIKI KAISHA, Toyota-shi (JP)

(21) Appl. No.: 18/818,826

(22) Filed: Aug. 29, 2024

(30) Foreign Application Priority Data
Oct. 11, 2023 (JP) 2023-175841

(51) Int. Cl. B60L 58/16; B60K 35/21; B60K 35/28; B60L 50/60; G01R 31/00; G01R 31/392; H01M 10/48

(52) U.S. Cl. CPC B60L 58/16; B60K 35/21; B60K 35/28; B60L 50/60; G01R 31/006; G01R 31/392; H01M 10/488; H01M 2220/20

(57) ABSTRACT

An electric vehicle according to an aspect of the present disclosure includes a driving motor, a battery configured to supply electric power to the driving motor, and a deterioration meter configured to measure a deterioration level of the battery. The deterioration meter includes an analog display unit configured to indicate the measured deterioration level by a needle, and the needle is movable only in a direction which indicates that the deterioration level increases. Further, the position of the needle is kept in a power-off state.

### CROSS REFERENCE TO RELATED APPLICATIONS

This application is based upon and claims the benefit of priority from Japanese patent application No. 2023-175841, filed on Oct. 11, 2023, the disclosure of which is incorporated herein in its entirety by reference.

### BACKGROUND

The present disclosure relates to an electric vehicle.

A battery including a battery gauge for measuring and displaying the remaining amount of electricity charged in the battery has been known as disclosed in, for example, Patent Literature 1. It should be noted that an electric vehicle runs as its driving motor is driven by electricity charged in a battery. Therefore, for example, when a used electric vehicle is sold or purchased, it is important to know the deterioration level of its battery.

### PATENT LITERATURE

Patent Literature 1: Japanese Unexamined Patent Application Publication No. 2015-028839

### SUMMARY

However, for example, although the battery disclosed in Patent Literature 1 includes a battery gauge, it does not include a deterioration meter that measures and displays the deterioration level of the battery. Therefore, in the battery disclosed in Patent Literature 1, it is necessary to measure the deterioration level of the battery by using a separate deterioration meter to know the deterioration level, and therefore, the deterioration level of the battery cannot be easily known. Therefore, the inventors have been making earnest efforts to develop an electric vehicle including a deterioration meter, and it is necessary that the deterioration level measured by the deterioration meter can be checked at any time and the measured deterioration level cannot be tampered with.

The present disclosure has been made in view of such circumstances, and provides an electric vehicle in which the deterioration level of a battery mounted thereon can be checked at any time and the measured deterioration level cannot be tampered with.

An electric vehicle according to an aspect of the present disclosure includes:
a driving motor;
a battery configured to supply electric power to the driving motor; and
a deterioration meter configured to measure a deterioration level of the battery, in which
the deterioration meter includes an analog display unit configured to indicate the measured deterioration level by a needle,
the needle is movable only in a direction which indicates that the deterioration level increases, and
a position of the needle is kept in a power-off state.

In the electric vehicle according to the present disclosure, the deterioration meter configured to measure the deterioration level of the battery includes the analog display unit configured to indicate the measured deterioration level by the needle. Further, the needle of the display unit is movable only in the direction which indicates that the deterioration level increases, and the position of the needle is kept in the power-off state. Therefore, it is possible to provide an electric vehicle in which the deterioration level of a battery mounted thereon can be checked at any time and the measured deterioration level cannot be tampered with.

The display unit may be disposed in an instrument panel inside the electric vehicle. By this configuration, the deterioration level of the battery can be checked at any time from inside the electric vehicle. Further, the display unit may also be provided in the battery. By this configuration, the deterioration level of the battery can be checked even when the battery is removed from the electric vehicle.

In the display unit, the deterioration level may be indicated by a plurality of areas having respective different colors. By this configuration, the deterioration level of the battery can be easily known.

The needle may be driven only when the deterioration level measured at this time is higher than the deterioration level measured at a last time.

According to the present disclosure, it is possible to provide an electric vehicle in which the deterioration level of a battery mounted thereon can be checked at any time and the measured deterioration level cannot be tampered with.

The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a block diagram showing a configuration of an electric vehicle according to a first embodiment;

FIG. 2 is a flowchart showing a method for controlling a deterioration meter according to the first embodiment;

FIG. 3 is a graph showing changes in battery temperature and those in resistance value over the time that has elapsed after the end of the running;

FIG. 4 is a graph showing relationships between resistance values and deterioration levels at various temperatures which are originally shown in a map;

FIG. 5 is a flowchart showing a method for controlling a deterioration meter according to a second embodiment; and

FIG. 6 is a graph showing relationships between sectional capacities and deterioration levels at various SOC changing amounts which are originally shown in a map.

### DESCRIPTION OF EMBODIMENTS

Specific embodiments according to the present disclosure will be described hereinafter in detail with reference to the drawings. However, the present disclosure is not limited to the below-shown embodiments. Further, for clarity of explanation, the following description and drawings are simplified as appropriate.

### First Embodiment

### <Configuration of Electric Vehicle>

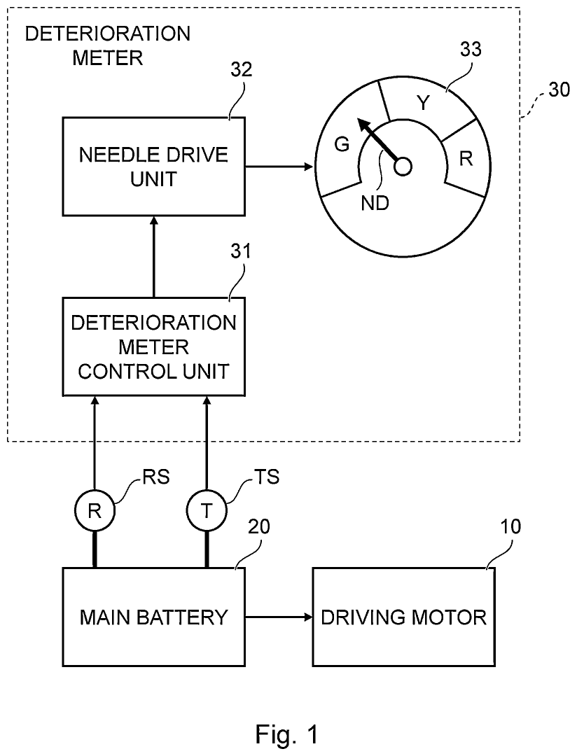

Firstly, a configuration of an electric vehicle according to a first embodiment will be described with reference to FIG. 1. FIG. 1 is a block diagram showing the configuration of the electric vehicle according to the first embodiment.

As shown in FIG. 1, the electric vehicle according to this embodiment includes a driving motor 10, a main battery 20, and a deterioration meter 30. Note that the deterioration meter 30 includes a deterioration meter control unit 31, a needle drive unit 32, and a display unit 33.

The driving motor 10 is a motor for driving a wheel(s) (not shown) of the electric vehicle by using electric power supplied from the main battery 20, and thereby making the electric vehicle travel.

The main battery 20 is connected to the driving motor 10 and supplies electric power charged therein to the driving motor 10. The voltage of the main battery 20 is, for example, 200 V. As shown in FIG. 1, the main battery 20 includes a temperature sensor TS that measures the temperature of the main battery 20 and a resistance sensor RS that measures the internal resistance (hereinafter simply referred to as the “resistance”) of the main battery 20.

Note that in FIG. 1, only the main battery 20 that supplies electric power to the driving motor 10 is shown, and a sub-battery and electrical equipment (auxiliary equipment) that operates by electric power supplied from and sub-battery are omitted. The voltage of the sub-battery is, for example, 12 V. Examples of the auxiliary equipment include headlights, blinkers, an air conditioner, a car navigation system, audio-equipment, and various control units.

As shown in FIG. 1, the electric vehicle according to this embodiment includes the deterioration meter 30. In the electric vehicle according to this embodiment, the deterioration meter control unit 31 acquires the temperature of the main battery 20 from the temperature sensor TS and acquires the resistance of the main battery 20 from the resistance sensor RS. Then, the deterioration meter control unit 31 obtains the deterioration level by referring to a map showing a relationship between the resistance of the main battery 20 and the deterioration level at the measured temperature.

Note that the deterioration meter control unit 31 outputs the obtained deterioration level to the needle drive unit 32 only when the obtained deterioration level is higher than the deterioration level obtained at the last time. The needle drive unit 32 drives a needle ND of the display unit 33 based on the deterioration level acquired from the deterioration meter control unit 31.

Note that although they are not shown in FIG. 1, the deterioration meter control unit 31 includes an arithmetic unit such as a CPU (Central Processing Unit), and a memory such as a RAM (Random Access Memory) and a ROM (Read Only Memory) in which various programs and various data including the above-described map are stored. That is, the deterioration meter control unit 31 functions as a computer and controls the needle drive unit 32 based on the aforementioned various programs.

Therefore, as hardware, the deterioration meter control unit 31 shown in FIG. 1 can be formed by the aforementioned CPU, the memory, and other circuits. Further, as software, the deterioration meter control unit 31 can be implemented by a program stored in the memory. That is, the deterioration meter control unit 31 can be implemented in various forms by hardware, software, or a combination thereof.

The deterioration meter control unit 31 stores in advance a map showing relationships between resistances and deterioration levels at various conceivable temperatures of the main battery 20. Note that although the memory (not shown) in which the map showing the relationships between resistances and the deterioration levels is stored is provided inside the deterioration meter control unit 31 in the example shown in FIG. 1, it may be provided outside the deterioration meter control unit 31.

As shown in FIG. 1, the display unit 33 is an analog display unit that indicates the measured deterioration level by the needle ND. Further, as described above, the needle ND is driven by the needle drive unit 32 which is, for example, a motor. In the example shown in FIG. 1, the needle ND rotates clockwise to indicate the deterioration level. Note that in the display unit 33, for example, the needle ND provided parallel to the vertical direction may move linearly in the horizontal direction to indicate the deterioration level.

Note that the needle ND of the display unit 33 can move only in the direction which indicates that the deterioration level increases and cannot move in the direction which indicates that the deterioration level decreases. In the example shown in FIG. 1, the needle ND of the display unit 33 can move only in the clockwise direction which indicates that the deterioration level increases. Therefore, it is possible to prevent anyone from tampering by moving the needle ND in the direction which indicates that the deterioration level decreases, for example. Further, the display unit 33 may be configured so that if someone tries to move the needle ND in the direction which indicates that the deterioration level decreases, for example, the needle ND is broken, or a stopper (not shown) for preventing the needle ND from moving in the direction which indicates that the deterioration level decreases is broken. By the above-described configuration, it is possible to prevent more reliably anyone from tampering by moving the needle ND in the direction which indicates that the deterioration level decreases.

Further, the position of the needle ND will be kept even when the electric vehicle is in a power-off state. Therefore, the deterioration level of the main battery 20 mounted on the electric vehicle can be checked by the display unit 33 at any time irrespective of whether the electric vehicle is in a power-on state or a power-off state. That is, in the electric vehicle according to this embodiment, the deterioration level of the main battery 20 mounted on the electric vehicle can be checked by the display unit 33 at any time, and the measured deterioration level cannot be tampered with.

The display unit 33 is provided, for example, in the instrument panel inside the electric vehicle. By this configuration, the deterioration level of the main battery 20 can be checked at any time from inside the electric vehicle. Further, the display unit 33 may be provided in the main battery 20 itself. By this configuration, the deterioration level of the main battery 20 can be checked even when the main battery 20 is removed from the electric vehicle.

In the example shown in FIG. 1, the deterioration level indicated by the needle ND is indicated by a plurality of areas having respective different colors, i.e., by a green area G, a yellow area Y, and a red area R. For example, the green area G, the yellow area Y, and the red area R mean “good”, “slightly deteriorated”, and “need to be replaced”, respectively. By this configuration, the deterioration level of the main battery 20 can be easily known.

As described above, in the electric vehicle according to this embodiment, the deterioration meter 30, which measures the deterioration level of the main battery 20, has the analog display unit 33 in which the measured deterioration level is indicated by the needle ND. Further, the needle ND of the display unit 33 is movable only in the direction which indicates that the deterioration level increases, and the position of the needle ND is kept even in the power-off state. Therefore, in the electric vehicle according to this embodiment, the deterioration level of the main battery 20 mounted on the electric vehicle can be checked at any time and the measured deterioration level cannot be tampered with.

### <Method for Controlling Deterioration Meter>

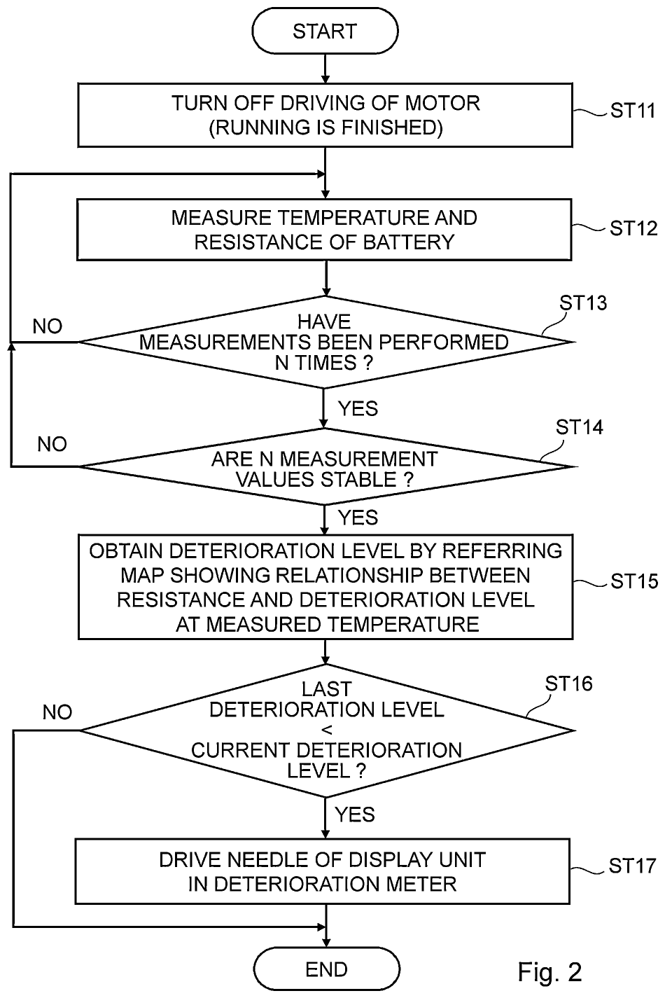

Next, a method for controlling the deterioration meter according to the first embodiment will be described with reference to FIG. 2. FIG. 2 is a flowchart showing the method for controlling the deterioration meter according to the first embodiment. Firstly, as shown in FIG. 2, after the driving of the driving motor 10 is turned off (i.e., stopped) and the electric vehicle thereby stops (Step ST11), the deterioration meter control unit 31 measures the temperature and resistance of the main battery 20 (Step ST12).

Next, as shown in FIG. 2, when the deterioration meter control unit 31 has not measured the temperature and resistance of the main battery 20 N times (No in Step ST13), the deterioration meter control unit 31 repeats the measurement of the temperature and resistance of the main battery 20, i.e., repeats the step ST12. On the other hand, when the deterioration meter control unit 31 has measured the temperature and resistance N times (Yes in Step ST13), the deterioration meter control unit 31 determines whether or not the last N measurement values are stable (Step ST14).

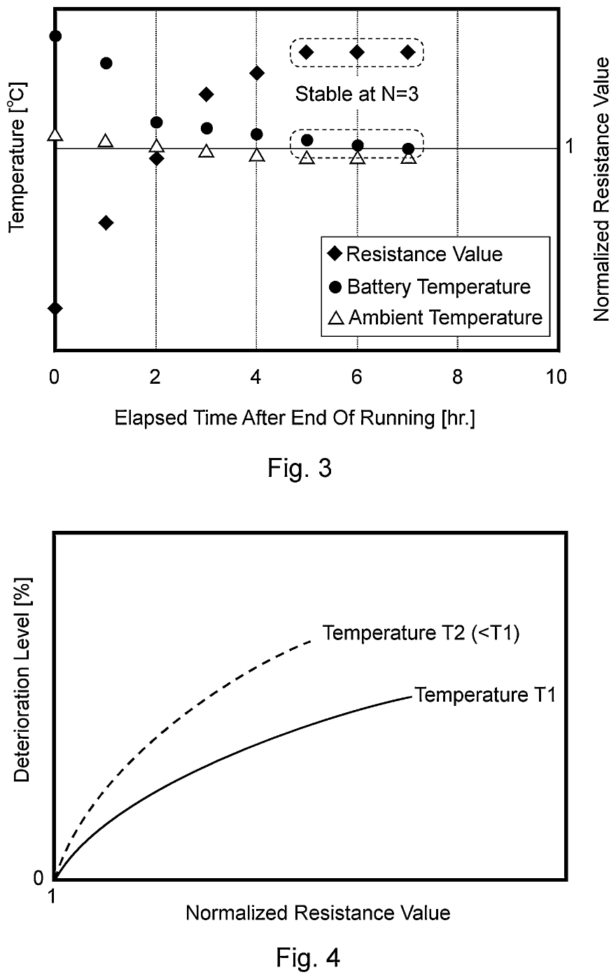

Note that FIG. 3 is a graph showing changes in battery temperature and those in resistance value over the time that has elapsed after the end of the running. The horizontal axis of FIG. 3 indicates the elapsed time (Time) after the end of the running, and the left vertical axis of FIG. 3 indicates the ambient temperature and the temperature of the main battery 20 (° C.). Further, the right vertical axis indicates the normalized resistance value. The normalized resistance value is a ratio R/R0_Tr between a measured resistance value R and an initial resistance value R0_Tr of the main battery 20 at a certain reference temperature Tr.

In the example shown in FIG. 3, the temperature and resistance of the main battery 20 are measured every one hour after the end of the running. In the example shown in FIG. 3, the predetermined number of times N is three (N=3), and when the difference between two consecutive measured values is within a predetermined reference range twice in a row, it is determined that the measured values are stable. Although the value or the like based on which it is determined whether the measured values are stable or not is the resistance of the main battery 20 in the example shown in FIG. 3, it may be the temperature of the main battery 20 or may be both the resistance and the temperature.

As shown in FIG. 3, the temperature of the main battery 20 which has increased during the running decreases and gets closes to the ambient temperature over the time that has elapsed after the end of the running. The resistance of the main battery 20 increases as the temperature of the main battery 20 deceases, and when the temperature of the main battery 20 stabilizes, the resistance of the main battery 20 also stabilizes.

As shown in FIGS. 2 and 3, when the N measurement values (i.e., values of N times of measurements) are not stable (No in Step ST14), the deterioration meter control unit 31 measures the temperature and resistance again. That is, the process returns to the step ST12. On the other hand, when the N measurement values are stable (Yes in Step ST14), the deterioration meter control unit 31 refers to a map showing a relationship between a resistance at the measured temperature and a deterioration level, and thereby obtains the deterioration level (Step ST15).

The step ST15 will be further described with reference to FIGS. 3 and 4. FIG. 4 is a graph showing relationships between resistance values and deterioration levels at various temperatures which are originally shown in the map. The horizontal axis of FIG. 4 indicates the normalized resistance value, and the vertical axis of FIG. 4 indicates the deterioration level (%). The normalized resistance value indicates a ratio between a resistance value R and an initial resistance value R0_T of the main battery 20 at each of various temperatures T.

Although the deterioration meter control unit 31 has a map showing relationships between resistance values and deterioration levels at various temperatures, only a map (i.e., a part of the map) at temperatures T1 and T2 (T2<T1) is shown in FIG. 4. Note that normalized resistance value at the temperature T1 indicates a ratio R/R0_T1 between a resistance value R and an initial resistance value R0_T1 of the main battery 20 at the temperature T1. The normalized resistance value at the temperature T2 indicates a ratio R/R0_T2 between a resistance value R and an initial resistance value R0_T2 of the main battery 20 at the temperature T2.

In the example shown in FIG. 3, the deterioration level is obtained by using an average value Ra of three resistance values enclosed by a dashed line and an average value Ta of three temperatures enclosed by a dashed line. Note that when the average value Ta at the temperatures enclosed by the dashed line in FIG. 3 is equal to T1, the deterioration level is obtained by using the map at the temperature T1 shown in FIG. 4. Specifically, the deterioration level corresponding to the normalized resistance value Ra/R0_T1 is obtained. Further, when the average value Ta at the temperatures enclosed in the dashed line in FIG. 3 is equal to T2, the deterioration level is obtained by using the map at the temperature T2 shown in FIG. 4. Specifically, the deterioration level corresponding to the normalized resistance value Ra/R0_T2 is obtained.

Next, as shown in FIG. 2, when the deterioration level obtained at this time is larger than the deterioration level obtained at the last time (Yes in Step ST16), the needle ND of the display unit 33 in the deterioration meter 30 is driven (Step ST17), and the control of the deterioration meter 30 is finished. Specifically, the deterioration meter control unit 31 outputs the deterioration level obtained at this time to the needle drive unit 32, and the needle drive unit 32 drives the needle ND of the display unit 33 based on the deterioration level acquired from the deterioration meter control unit 31. On the other hand, when the deterioration level determined at this time is equal to or lower than the deterioration level determined at the last time (No in step ST16), the control of the deterioration meter 30 is finished without performing the step ST17. This is because the deterioration level at the present time never becomes smaller than the deterioration level in the past.

### Second Embodiment

A configuration of an electric vehicle according to a second embodiment is substantially the same as that of the electric vehicle according to the first embodiment shown in FIG. 1. Note that as shown in FIG. 1, in the electric vehicle according to the first embodiment, the deterioration meter control unit 31 determines the deterioration level based on the temperature and resistance of the main battery 20. In contrast, in the electric vehicle according to this embodiment, the deterioration meter control unit 31 determines the deterioration level based on the SOC changing amount and the sectional capacity of the main battery 20 for each running. That is, the deterioration meter control unit 31 stores in advance a map showing relationships between sectional capacities and deterioration levels at various conceivable SOC changing amounts.

### <Method for Controlling Deterioration Meter>

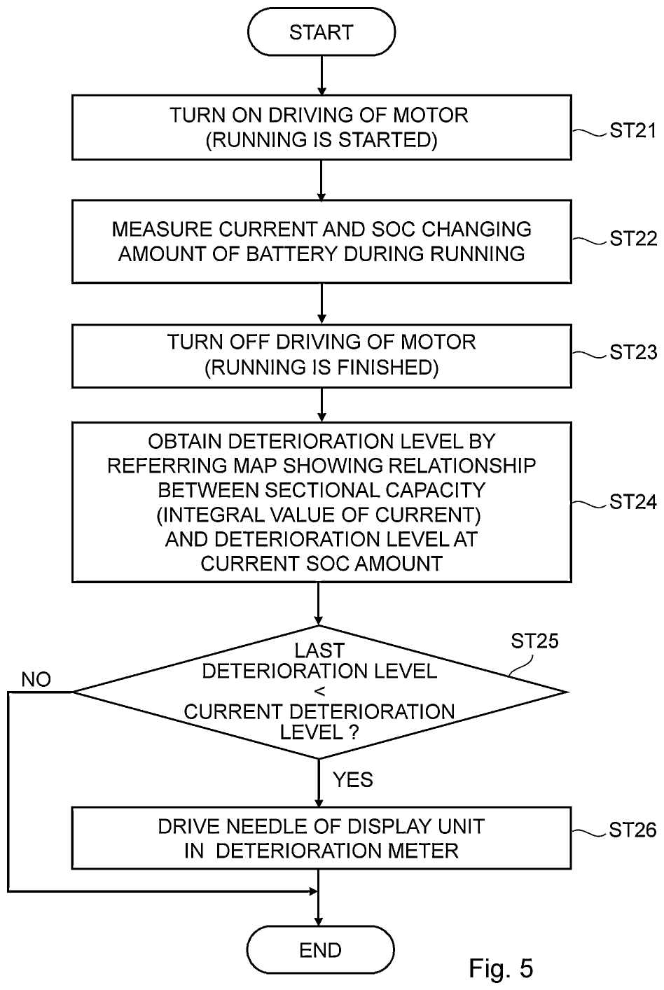

Next, a method for controlling the deterioration meter according to the second embodiment will be described with reference to FIG. 5. FIG. 5 is a flowchart showing the method for controlling the deterioration meter according to the second embodiment. Firstly, as shown in FIG. 5, after the driving of the driving motor 10 is turned on (i.e., started) and the electric vehicle thereby starts running (Step ST21), the deterioration meter control unit 31 measures the electric current and the SOC changing amount during the running (Step ST22).

Next, as shown in FIG. 2, after the driving of the driving motor 10 is turned off (i.e., stopped) and the electric vehicle thereby stops the running (Step ST23), the deterioration meter control unit 31 refers to a map showing a relationship between a sectional capacity (the integral value of electric current) and a deterioration level at the SOC changing amount obtained during the current running, and thereby determines the deterioration level (Step ST24).

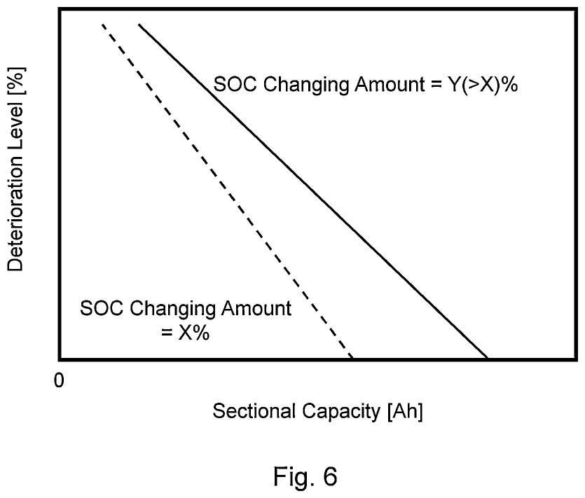

The step ST24 will be described with reference to FIG. 6. FIG. 6 is a graph showing relationships between sectional capacities and deterioration levels at various SOC changing amounts which are originally shown in a map. The horizontal axis of FIG. 6 indicates the sectional capacity (Ah), and the vertical axis of FIG. 6 indicates the deterioration level (%). The sectional capacity is the integral value of electric current (discharging current and charging current) that has flowed through the main battery 20 during the running. Note that the discharging current is defined as a positive current and the charging current is defined as a negative current.

Although the deterioration meter control unit 31 has a map showing relationships between sectional capacities and deterioration levels at various SOC changing amounts, only a map (i.e., a part of the map) at SOC changing amounts of X % and Y % (Y>X) is shown as a representative example in FIG. 6. When the SOC changing amount in the current running is X %, the deterioration level corresponding to the sectional capacity in the current running is obtained by using a map at the SOC changing amount=X % shown in FIG. 6. Further, when the SOC changing amount in the current running is Y %, the deterioration level corresponding to the sectional capacity in the current running is obtained by using a map at the SOC changing amount=Y % shown in FIG. 6.

Next, as shown in FIG. 5, when the deterioration level obtained at this time is larger than the deterioration level obtained at the last time (Yes in Step ST25), the needle ND of the display unit 33 in the deterioration meter 30 is driven (Step ST26), and the control of the deterioration meter 30 is finished. Specifically, the deterioration meter control unit 31 outputs the deterioration level obtained at this time to the needle drive unit 32, and the needle drive unit 32 drives the needle ND of the display unit 33 based on the deterioration level acquired from the deterioration meter control unit 31. On the other hand, when the deterioration level determined at this time is equal to or lower than the deterioration level determined at the last time (No in step ST25), the control of the deterioration meter 30 is finished without performing the step ST26. This is because the deterioration level at the present time never becomes smaller than the deterioration level in the past. The rest of the configuration is similar to that of the first embodiment, and therefore the detailed description thereof is omitted.

Note that the present disclosure is not limited to the above-described embodiments, and they may be modified as appropriate without deviating from the scope and spirit of the disclosure. For example, as shown in the first and second embodiments, the method for obtaining a deterioration level performed by the deterioration meter 30 is not limited to any particular methods, and various variations thereof are conceivable. Further, the present disclosure promotes the use of electric vehicles and thereby contributes to carbon neutrality, decarbonization, and sustainable development goals (SDGs: Sustainable Development Goals).

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. An electric vehicle comprising:
a driving motor;
a battery configured to supply electric power to the driving motor; and
a deterioration meter configured to measure a deterioration level of the battery, wherein
the deterioration meter includes an analog display unit configured to indicate the measured deterioration level by a needle,
the needle is movable only in a direction which indicates that the deterioration level increases, and
a position of the needle is kept in a power-off state.

2. The electric vehicle according to claim 1, wherein the display unit is provided in an instrument panel inside the electric vehicle.

3. The electric vehicle according to claim 2, wherein the display unit is also provided in the battery.

4. The electric vehicle according to claim 1, wherein the deterioration level is indicated by a plurality of areas having respective different colors.

5. The electric vehicle according to claim 1, wherein the needle is driven only when the deterioration level measured at this time is higher than the deterioration level measured at a last time.
